(19) United States
(12) Patent Application Publication
(10) Pub. No.: US 2025/0391939 A1
(43) Pub. Date: Dec. 25, 2025

(54) OPTIMIZATION METHOD AND OPTIMIZATION SYSTEM OF ELECTROLYTE FOR LITHIUM SECONDARY BATTERY, ELECTROLYTE FOR LITHIUM SECONDARY BATTERY, AND LITHIUM SECONDARY BATTERY

(71) Applicant: The Industry & Academic Cooperation in Chungnam National University (IAC), Daejeon (KR)

(72) Inventors: Kosan ROH, Daejeon (KR); Seung-Wan Song, Sejong-si (KR); Jaehyun Park, Daejeon (KR); Taekeon Oh, Daejeon (KR); Kihun An, Daejeon (KR)

(73) Assignee: The Industry & Academic Cooperation in Chungnam National University (IAC), Daejeon (KR)

(21) Appl. No.: 18/953,598

(22) Filed: Nov. 20, 2024

(30) Foreign Application Priority Data
Jun. 21, 2024 (KR) 10-2024-0081369

(51) Int. Cl. H01M 10/48; G01R 31/367; G01R 31/378; H01M 10/0525; H01M 10/44

(52) U.S. Cl. CPC H01M 10/484; G01R 31/367; H01M 10/0525; H01M 10/44; G01R 31/378; H01M 2300/0034; H01M 2300/0037

(57) ABSTRACT

Provided are an optimization method of an electrolyte for lithium secondary batteries, an optimization system of an electrolyte for lithium secondary batteries, an electrolyte for lithium secondary batteries, and a lithium secondary battery, the optimization method including preparing a first data set including a first formulation and data obtained from the first formulation, obtaining a second formulation from the first data set by Bayesian Optimization, obtaining data from the second formulation, preparing an updated first data set including an updated first formulation and data obtained from the updated first formulation by updating the first formulation and the data obtained from the first formulation by using the second formulation and the data obtained from the second formulation, respectively, and determining whether termination conditions are satisfied, wherein the obtaining of the second formulation, the obtaining of data from the second formulation, and the preparing of the updated first data set are repeated until the termination conditions are satisfied, the data obtained from the first formulation includes first data obtained from an electrolyte prepared by the first formulation and second data obtained from a lithium secondary battery prepared by using the electrolyte, and the second data includes a latter retention and a final discharge capacity.

### CROSS-REFERENCE TO RELATED APPLICATION

This application is based on and claims priority under 35 U.S.C. § 119 to Korean Patent Application No. 10-2024-0081369, filed on Jun. 21, 2024, in the Korean Intellectual Property Office, the disclosure of which is incorporated by reference herein in its entirety.

### BACKGROUND

### 1. Field

The disclosure relates to an optimization method and an optimization system of an electrolyte for lithium secondary batteries, an electrolyte for lithium secondary batteries, and a lithium secondary battery, and more particularly, to an optimization method of an electrolyte for lithium secondary batteries capable of effectively deriving an electrolyte for lithium secondary batteries having safety and excellent charging and discharging characteristics by combining machine learning and Bayesian Optimization.

This study was conducted with the support of Samsung Research Funding Center (Project No.: SRFC-MA2202-04).

### 2. Description of the Related Art

Lithium secondary batteries are used as power sources for portable electronic devices such as smartphones and laptop computers and electric vehicles. An electrolyte including an organic solvent is commonly used in lithium secondary batteries. Because organic solvents are flammable, there are safety issues such as the possibility of ignition during charging and discharging of lithium secondary batteries including an organic solvent-containing electrolyte. Lithium secondary batteries should provide excellent charging and discharging characteristics in addition to safety. In order to derive an electrolyte for lithium secondary batteries satisfying safety and excellent charging and discharging characteristics, combinations of various elements constituting the electrolyte may be considered. However, there are realistic limitations in performing various tests, such as safety tests and charging and discharging tests, on all combinations of various components constituting the electrolytes.

### SUMMARY

Conventionally, an optimized electrolyte composition was derived after trial and error via repeated experiments performed by researchers with experiences in combination of various components constituting electrolytes.

A charging/discharging test of lithium secondary batteries requires, for example, a long time. Therefore, deriving of an optimized electrolyte composition via trial and error by repeated experiments is very time-consuming and inefficient.

Therefore, a method of more effectively designing an experiment capable of deriving an electrolyte for lithium secondary batteries satisfying safety and excellent charging and discharging characteristics.

Provided is an optimization method of an electrolyte for lithium secondary batteries capable of more effectively deriving an electrolyte for lithium secondary batteries having safety and excellent charging and discharging characteristics by combining machine learning and Bayesian Optimization.

Provided is an optimization system of an electrolyte for lithium secondary batteries capable of more effectively deriving an electrolyte for lithium secondary batteries having safety and excellent charging and discharging characteristics by combining machine learning and Bayesian Optimization.

Provided is an electrolyte for lithium secondary batteries prepared from a formulation obtained by the optimization method.

Provided is a lithium secondary battery including the electrolyte for lithium secondary batteries.

Additional aspects will be set forth in part in the description which follows and, in part, will be apparent from the description, or may be learned by practice of the presented embodiments of the disclosure.

According to an aspect of the disclosure, a method of optimizing an electrolyte for a lithium secondary battery includes preparing a first data set including a first formulation and data obtained from the first formulation,
obtaining a second formulation from the first data set by Bayesian Optimization, obtaining data from the second formulation,
preparing an updated first data set including an updated first formulation and data obtained from the updated first formulation by updating the first formulation and the data obtained from the first formulation by respectively using the second formulation and the data obtained from the second formulation, and determining whether termination conditions are satisfied,
wherein the obtaining of the second formulation, the obtaining of data from the second formulation, and the preparing of the updated first data set are repeated until the termination conditions are satisfied,
wherein the data obtained from the first formulation includes first data obtained from an electrolyte prepared by the first formulation and second data obtained from a lithium secondary battery prepared by using the electrolyte, and the second data includes a latter retention and a final discharge capacity.

According to another aspect of the disclosure, a system for optimizing an electrolyte for a lithium secondary battery includes an evaluator configured to obtain data from a first formulation or a second formulation,
a formulation generator configured to obtain the second formulation by applying the first data set including the first formulation and the data obtained from the first formulation to Bayesian Optimization;
an updater configured to prepare an updated first data set including an updated first formulation and data obtained from the updated first formulation by updating the first formulation and the data obtained from the first formulation by respectively using the second formulation and data obtained from the second formulation, and
a termination determiner configured to determine whether termination conditions are satisfied,
wherein the obtaining of the second formulation, the obtaining of data from the second formulation, and the preparing of the updated first data set are repeated until the termination conditions are satisfied,
the data obtained from the first formulation includes first data obtained from an electrolyte prepared by the first formulation and second data obtained from a lithium secondary battery prepared by using the electrolyte, and
the second data includes a latter retention and a final discharge capacity.

According to another aspect of the disclosure,
an electrolyte for lithium secondary batteries is prepared from the first formulation obtained by the optimization method of the electrolyte for lithium secondary batteries.

According to another aspect of the disclosure,
a lithium secondary battery includes the electrolyte for lithium secondary batteries.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a flowchart of an optimization method of an electrolyte for lithium secondary batteries according to an embodiment;

FIG. 2 is a functional block diagram of an optimization system for a lithium secondary battery according to an embodiment;

FIG. 3 is a functional block diagram of an optimization system for a lithium secondary battery according to another embodiment;

FIG. 4 is a block diagram of an optimization apparatus for a lithium secondary battery according to another embodiment;

FIGS. 5A and 5B are graphs showing correlation between retention and latter retention shown in Table 2 of Evaluation Example 2;

FIG. 6 is a graph showing coefficient of determination (R²) and root mean square error (RMSE) of initial discharge capacity (discharge capacity at 1st cycle) and final discharge capacity (discharge capacity at 100th cycle) of Samples 1 to 15 measured in Evaluation Example 1; and

FIG. 7 is a schematic diagram of a lithium secondary battery according to an embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” if preceding a list of elements, modify the entire list of elements and do not modify the individual elements of the list.

The present inventive concept described below allows various changes and numerous embodiments, particular embodiments will be illustrated in the drawings and described in detail in the written description. However, this is not intended to limit the present inventive concept to particular modes of practice, and it is to be appreciated that all modifications, equivalents, and substitutes that do not depart from the spirit and technical scope of the present inventive concept are encompassed in the present inventive concept.

The terms used herein are merely used to describe particular embodiments and are not intended to limit the present inventive concept. An expression used in the singular encompasses the expression of the plural, unless it has a clearly different meaning in the context. In the present specification, it is to be understood that the terms such as “including” or “having” etc., are intended to indicate the existence of the features, numbers, operations, elements, parts, components, materials, or combinations thereof disclosed in the specification, and are not intended to preclude the possibility that one or more other features, numbers, operations, elements, parts, components, materials, or combinations thereof may exist or may be added. As used herein, the “/” may be interpreted as either “and” or “or” depending on situations.

In the drawings, thicknesses of various layers and regions may be enlarged or reduced for clarity. Throughout the specification, like reference numerals denote like elements. Throughout the specification, it will be understood that when one element such as layer, film, region, or plate, is referred to as being “on” another element, it may be directly on the other element, or intervening elements may also be present therebetween. Although the terms first, second, etc. may be used herein to describe various components, these components should not be limited by these terms. These terms are only used to distinguish one component from another. In this specification and drawings, components having substantially the same functional configuration are referred to by the same reference numerals, and redundant descriptions are omitted.

Hereinafter, an optimization method, an optimization system, and an optimization apparatus of an electrolyte for lithium secondary batteries, an electrolyte for lithium secondary batteries, and a lithium secondary battery according to embodiments will be described in more detail.

### [Optimization Method of Electrolyte for Lithium Secondary Battery]

A method of optimizing an electrolyte for lithium secondary batteries according to an embodiment includes: preparing a first data set including a first formulation and data obtained from the first formulation; obtaining a second formulation from the first data set by Bayesian Optimization; obtaining data from the second formulation; preparing an updated first data set including an updated first formulation and data obtained from the updated first formulation by updating the first formulation and the data obtained from the first formulation by respectively using the second formulation and the data obtained from the second formulation; and determining whether termination conditions are satisfied. The obtaining of the second formulation, the obtaining of data from the second formulation, and the preparing of the updated first data set are repeated until the termination conditions are satisfied. The data obtained from the first formulation includes first data obtained from an electrolyte prepared by the first formulation and second data obtained from a lithium secondary battery prepared by using the electrolyte. The second data includes a latter retention (i.e., latter capacity retention) and a final discharge capacity.

The optimization method of an electrolyte for lithium secondary batteries of the disclosure may derive an optimized composition of the electrolyte by an probabilistic approach based on statistics by using Bayesian Optimization. Therefore, the optimized electrolyte composition may be derived more simply with higher efficiency compared to a method for deriving an optimized electrolyte composition that requires a long time due to repeated experiments.

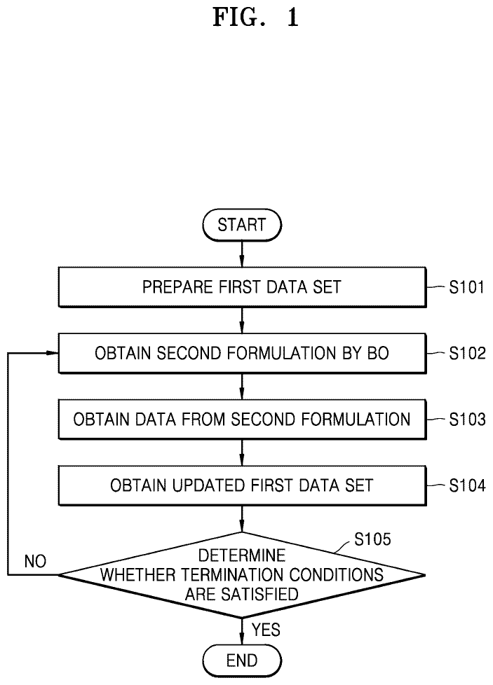

FIG. 1 is a flowchart of an optimization method of an electrolyte for lithium secondary batteries according to an embodiment. Referring to FIG. 1, the optimization method of the electrolyte for lithium secondary batteries according to an embodiment will be described in more detail.

First, the first data set including the first formulation and data obtained from the first formulation is prepared (S101).

The first data set includes the first formulation. For example, the first formulation may include one composition or may be a composition set including a plurality of compositions.

The first data set may include data obtained from the first formulation. The data obtained from the first formulation may include, for example, primary data such as a physical property measurement on the first formulation, and a charging and discharging characteristic measurement on the lithium secondary battery including the electrolyte prepared by using the first formulation. The data obtained from the first formulation may include secondary data that is an estimate obtained by additional calculation by manuals and/or software using the primary data. The data obtained from the first formulation may include, for example, a combination of the primary data and the secondary data.

The data obtained from the first formulation includes first data measured on the electrolyte prepared according to the first formulation and second data measured on the lithium secondary battery prepared by using the electrolyte. The second data includes a latter retention and a final discharge capacity. A physical property measurement obtained from the first formulation may include, for example, a first physical property measurement on the electrolyte prepared by the first formulation and a second physical property measurement on the lithium secondary battery prepared by using the electrolyte. The first physical property measurement may include a self-extinguishing time. The second physical property measurement may include a latter retention and a final discharge capacity.

The first data set may consist of, for example, one composition and data on the composition. The first data set may include one electrolyte composition, first data on the electrolyte prepared according to the electrolyte composition, and second data on the lithium secondary battery including the prepared electrolyte. The first data set may include, for example, one electrolyte composition, a first physical property measurement on the electrolyte prepared according to the electrolyte composition, and a second physical property measurement on the lithium secondary battery including the prepared electrolyte.

More generally, the first data set may consist of a plurality of compositions and data on each of the plurality of compositions. The first data set may include a set of a plurality of electrolyte compositions, a set of first data on the plurality of electrolytes prepared according to the plurality of electrolyte compositions respectively, and a set of second data on the lithium secondary batteries respectively including the prepared plurality of electrolytes. The first data set may include a set of a plurality of electrolyte compositions, a set of the first physical property measurements on the plurality of electrolytes respectively prepared according to the plurality of electrolyte compositions, and a set of the second physical property measurements on lithium secondary batteries respectively including the prepared plurality of electrolytes. In the case where the first data set includes a plurality of compositions and a set of physical property data on each of the plurality of compositions, the second formulation may be obtained more effectively.

Then, the second formulation is obtained from the first data set by Bayesian Optimization (S102).

For example, the second formulation is derived, for example, by subjecting the first data set including a set of a plurality of compositions and a set of data on each of the plurality of compositions to Bayesian Optimization, as a machine learning.

Bayesian Optimization refers to a method of obtaining an estimate result of an objective function in the form of a posterior probability density function by using n data sets (e.g., (composition a, electrolyte physical property a, and lithium secondary battery lifespan characteristic a), (composition b, electrolyte physical property b, and lithium secondary battery lifespan characteristic b), . . . , (composition n, electrolyte physical property n, and lithium secondary battery lifespan characteristic n)) by a surrogate model, and obtaining composition n+1 that maximizes an acquisition function consisting of statistical figures such as average, standard deviation, and probability density based thereon.

That is, Bayesian Optimization refers to, for example, a method of constructing a surrogate model for an unknown objective function by using sampled N data sets, and choosing a new composition capable of minimizing uncertainty of the objective function or maximizing an expected value of the objective function. The choosing of the new composition may be performed, for example, by using the acquisition function. To choose the new composition, for example, an acquisition function designed by appropriately combining uncertainty of the objective function and the expected value of the objective function is used and a new composition having a maximum value of the acquisition function is chosen.

Subsequently, data is obtained from the second formulation (S103).

The second formulation may include one composition or may be a composition set including a plurality of compositions.

Data is obtained from the composition or the composition set constituting the second formulation. The data obtained from the second formulation may include, for example, primary data such as a physical property measurement on the second formulation, and a charging and discharging characteristic measurement on the lithium secondary battery including the electrolyte prepared by using the second formulation. The data obtained from the second formulation may include secondary data that is an estimate obtained by additional calculation by manuals and/or software using the primary data. The data obtained from the second formulation may include, for example, a combination of the primary data and the secondary data.

For example, the data obtained from the second formulation includes first data measured on the electrolyte prepared according to the second formulation and second data measured on the lithium secondary battery prepared by using the electrolyte prepared according to the second formulation. For example, a physical property measurement obtained from the second formulation may include, for example, a first physical property measurement on the electrolyte prepared by the second formulation and a second physical property measurement on the lithium secondary battery prepared by using the electrolyte prepared by the second formulation.

The second formulation may be, for example, one composition, and data obtained from the second formulation may be data for the one composition. Data obtained from the second formulation may include, for example, first data on the electrolyte prepared according to the one electrolyte composition and second data on the lithium secondary battery including the prepared electrolyte.

The second formulation may be, for example, one composition, and the physical property measurement obtained from the second formulation may be a physical property measurement according to the one composition. The physical property measurement obtained from the second formulation includes, for example, a first physical property measurement on the electrolyte prepared according to the one electrolyte composition, and a second physical property measurement on the lithium secondary battery including the prepared electrolyte.

More generally, the second formulation may include, for example, a plurality of compositions, and the data obtained from the second formulation may be, for example, a set of data on each of the plurality of compositions. The data obtained from the second formulation may include, for example, a set of first data on each of the plurality of electrolytes prepared according to the plurality of electrolyte compositions respectively, and a set of second data on the lithium secondary batteries respectively including the prepared plurality of electrolytes.

More generally, the second formulation may include, for example, a plurality of compositions, and the physical property measurement obtained from the second formulation may be, for example, a physical property measurement on each of the plurality of compositions. The physical property measurement obtained from the second formulation may include, for example, a set of first physical property measurements on the plurality of electrolytes prepared according to the plurality of electrolyte compositions respectively, and a set of second physical property measurements for the lithium secondary batteries respectively including the prepared plurality of electrolytes.

Next, the first formulation and the data obtained from the first formulation are respectively updated by using the second formulation and the data obtained from the second formulation to prepare the updated first data set including the updated first formulation and the data obtained from the updated first formulation (S104).

The updated first data set may be prepared, for example, by adding the second formulation and the physical property measurement obtained from the second formulation to the first data set including the initial first formulation and the physical property measurement obtained from the first formulation.

For example, in the case where the first data set includes n data sets (e.g., (composition a, electrolyte physical property a, and lithium secondary battery lifespan characteristic a), (composition b, electrolyte physical property b, and lithium secondary battery lifespan characteristic b), . . . , (composition n, electrolyte physical property n, and lithium secondary battery lifespan characteristic n)), an updated first data set including n+1 data sets may be prepared by adding a new data set (e.g., composition n+1, electrolyte physical property n+1, and lithium secondary battery lifespan characteristic n+1) derived by Bayesian Optimization, to the first data set.

More generally, the data set added to the first data set may be in a plural number. For example, in the case where the first data set includes n data sets, an updated first data set including n+m data sets may be prepared by adding new m data sets derived by using Bayesian Optimization, to the first data set.

Next, it is determined whether termination conditions are satisfied (S105).

The termination conditions may be, for example, a fixed experimental budget performing termination when a preset number of experiments is reached, a convergence threshold performing termination when the objective function converges to a preset limit, a performance threshold performing termination when an output exceeds a preset value, no improvement in acquisition function performing termination unless an acquisition function is further improved, a resources constrains performing termination when a resource such as time required for an experiment reaches a preset value, and manual interruption performing termination depending on a user's determination. The termination conditions may be, for example, whether the number of performing Bayesian Optimization exceeds a preset number of times, whether the number of data included in the data set exceeds a preset number, or whether the physical property measurement obtained from the updated first formulation exceeds a preset criterion, but are not limited thereto, and may be selected according to required conditions.

The termination conditions may be, for example, whether there is at least one data including physical properties exceeding the reference physical property of the lithium secondary battery among the n+1 data sets including the updated first formulation and the physical property measurement obtained from the updated first formulation ((e.g., (composition a, electrolyte physical property a, and lithium secondary battery lifespan characteristic a), (composition b, electrolyte physical property b, and lithium secondary battery lifespan characteristic b), . . . , (composition n, electrolyte physical property n, and lithium secondary battery lifespan characteristic n), and (composition n+1, electrolyte physical property n+1, and lithium secondary battery lifespan characteristic n+1)).

The termination conditions may be, for example, the number of repeating Bayesian Optimization, the number of data included in the data set, the physical property measurement, or any combination thereof.

The number of repeating Bayesian Optimization may be, for example, 100 or less, 50 or less, 30 or less, 20 or less, 10 or less, or 5 or less.

The number of data included in the data set may be, for example, 1000 or less, 500 or less, 100 or less, 50 or less, 30 or less, 20 or less, or 10 or less.

Upon determination that the termination conditions are satisfied, the optimization is terminated and the updated first formulation at the time of termination is used as a result.

If the termination conditions are not satisfied, the obtaining of the second formulation, the obtaining of the physical property measurement from the second formulation, and the preparing of the updated first data set are sequentially performed again.

Until the termination conditions are satisfied, the obtaining of the second formulation, the obtaining of the physical property measurement from the second formulation, and the preparing of the updated first data set are repeated.

In the optimization method of an electrolyte for lithium secondary batteries, the data obtained from the first formulation (e.g., physical property measurement) includes first data obtained from an electrolyte prepared by the first formulation (e.g., first physical property measurement) and second data obtained from a lithium secondary battery prepared by using the electrolyte (e.g., second physical property measurement). Because the second data (e.g., the second physical property measurement) includes a latter retention and a final discharge capacity, the optimized electrolyte composition may be derived more simply and effectively. If the second data (e.g., the second physical property measurement) does not include a latter retention and a final discharge capacity, the number and/or time of Bayesian Optimization required to derive the optimized electrolyte composition may increase. That is, efficiency of Bayesian Optimization for deriving the optimized electrolyte composition may decrease.

In the obtaining of the second formulation from the first data set by Bayesian Optimization (S102) of the optimization method of the electrolyte for lithium secondary batteries, the second formulation may be, for example, a composition corresponding to a maximum value of the acquisition function or an approximate value thereof.

In the case where the second formulation includes one composition, the second formulation may be one composition corresponding to the maximum value of the acquisition function.

Alternatively, in the case where the second formulation includes a plurality of compositions, the second formulation may include a composition corresponding to the maximum value of the acquisition function and at least one composition corresponding to approximate values thereof.

In addition to the composition corresponding to the maximum value of the acquisition function, the second formulation may include compositions corresponding to approximate values of the maximum value selected in the order of standard deviation (or variance) from the largest among points where the values of the acquisition function are in the top n % of the Gaussian process posterior probability density function of the objective function. For example, the n % may be 1%, 3%, 5%, 10% 15%, or 20%.

The maximum value of the acquisition function may include, for example, a maximum value of the acquisition function corresponding to the first data or an approximate value thereof and a maximum value of the acquisition function corresponding to the second data or an approximate value thereof, and a weight applied to the maximum value of the acquisition function corresponding to the first data or an approximate value thereof may be different from a weight applied to the maximum value of the acquisition function corresponding to the second data or an approximate value thereof.

The maximum value of the acquisition function may include, for example, the maximum value of the acquisition function corresponding to the first data or an approximate value thereof and the maximum value of the acquisition function corresponding to the second data or an approximate value thereof, and the weight applied to the maximum value of the acquisition function corresponding to the first data or an approximate value thereof may be lower than the weight applied to the maximum value of the acquisition function corresponding to the second data or an approximate value thereof. The first data may be, for example, a first physical property, and the second data may be, for example, a second physical property.

The weight of the first data on the electrolyte prepared according to the second formulation may be lower the weight of the second data on the lithium secondary battery prepared by using the electrolyte.

The weight of the first data on the electrolyte prepared according to the second formulation may be 90% or less, 70% or less, 50% or less, 30% or less, 10% or less, or 5% or less of the weight of the second data on the lithium secondary battery prepared by using the electrolyte.

Because the weight of the first data on the electrolyte prepared according to second formulation is lower than the weight of the second data on the lithium secondary battery prepared by using the electrolyte as described above, the deriving of the second formulation by Bayesian Optimization may be more dependent on the second data on the lithium secondary battery than on the first data on the electrolyte.

Bayesian Optimization includes a surrogate model and an acquisition function.

The surrogate model is a machine learning model showing probability estimates of a form of the objective function. The surrogate model is, for example, a model in which the relationship between a hyperparameter set and a generalization performance set is modeled.

The surrogate model may include, for example, Gaussian process, Neural Networks, or Tree-structured Parzen Estimators (TPE). The surrogate model may be, for example, the Gaussian process.

The acquisition function is a function recommending a composition to be additionally examined based on, for example, probability estimates about the form of the objective function. By combining statistical figures such as average, standard deviation, and probability density based on the posterior probability density function obtained in the surrogate model, a composition corresponding to a maximum value of the acquisition function calculated therefrom or an approximate value may be recommended.

The acquisition function may include, for example, Expected Improvement (EI), Probability of Improvement (POI), Lower Confidence Bound (LCB), Upper Confidence Bound (UCB), or Entropy Search (ES). The acquisition function may be, for example, Expected Improvement.

The acquisition function may be, for example, a constrained acquisition function having constraining conditions. The constrained acquisition function may allow, for example, a composition satisfying constraining conditions multiplied by, for example, a probability satisfying the constraining conditions, to be included as a recommendation candidate. Alternatively, the constrained acquisition function may exclude a composition not satisfying the constraining conditions from the recommendation candidate, for example, by processing a value of the acquisition function to 0 The constraining conditions of the acquired function, may be, for example, the physical property measurement

In the optimization method of an electrolyte for lithium secondary batteries, the latter retention is, for example, a ratio Cf/Ca of a final discharge capacity Cf at the last cycle to a latter discharge capacity Ca at a cycle over 20% of the total number of cycles from the first cycle.

The latter discharge capacity may be a discharge capacity at a cycle, for example, over 30% or more, 50% or more, 60% or more, 70% or more, 80% or more, or 90% or more of the total number of cycles from the first cycle.

The latter retention of the lithium secondary battery prepared by using the electrolyte prepared by using the formulation derived by the optimization method of an electrolyte for lithium secondary batteries may be, for example, 90% or more, 91% or more, 92% or more, or 93% or more.

In the optimization method of an electrolyte for lithium secondary batteries, the final discharge capacity Cf is a discharge capacity at the last cycle while the retention is measures.

The final discharge capacity of the lithium secondary battery prepared by using the electrolyte prepared by using the formulation derived by the optimization method of an electrolyte for lithium secondary batteries may be, for example, 148 mAh/g or more, 150 mAh/g or more, 155 mAh/g or more, or 160 mAh/g or more.

In the optimization method of an electrolyte for lithium secondary batteries, the second data may further include, for example, a retention.

The retention is, for example, a ratio Cf/Ci of a discharge capacity Cf at the last cycle to a discharge capacity Ci of the first cycle.

The retention of the lithium secondary battery prepared by using the electrolyte prepared by using the formulation derived by the optimization method of an electrolyte for lithium secondary batteries may be, for example, 80% or more, 81% or more, 82% or more, or 83% or more.

In the optimization method of an electrolyte for lithium secondary batteries, the second data may further include, for example, cumulative discharge capacity over cycle (CDCC). A cumulative discharge capacity of the lithium secondary battery prepared by using the electrolyte prepared by using the formulation derived by the optimization method of an electrolyte for lithium secondary batteries is a sum of discharge capacities of the cycles from the first cycle to the last cycle in the charging and discharging cycles.

In the optimization method of an electrolyte for lithium secondary batteries, the first data may include, for example, self-extinguishing time.

The self-extinguishing time is a time taken for ignition to end after ignition of the electrolyte.

The self-extinguishing time of the electrolyte by using the formulation derived by the optimization method of an electrolyte for lithium secondary batteries may be, for example, 6 sec/g or less, 5 sec/g or less, 4 sec/g or less, 3 sec/g or less, 2 sec/g or less, or 1 sec/g or less.

In the optimization method of an electrolyte for lithium secondary batteries, the first data may further include ionic conductivity. Although ionic conductivity of the electrolyte has a relatively low correlation with the charging and discharging characteristics of the lithium secondary battery, the ionic conductivity may be used as auxiliary physical property data.

In the optimization method of an electrolyte for lithium secondary batteries, the first formulation may include, for example, a primary formulation prepared empirically or by sampling, a secondary formulation as an estimate prepared by additional calculation from the primary formulation, or any combination thereof.

The first formulation may include, for example, one composition or a plurality of composition set empirically prepared. The first formulation may include, for example, the primary formulation prepared empirically or by sampling.

By empirically preparing the first formulation, the first formulation and data obtained from the first formulation, for example, a first data set including the physical property measurements may be prepared. Bayesian Optimization may be performed by using the first data set.

Alternatively, the first formulation may be prepared, for example, by sampling. The sampling may be performed without an experiment.

The sampling may include, for example, grid sampling, random sampling, latin hypercube sampling, or orthogonal sampling.

The sampling may be, for example, latin hypercube sampling. The latin hypercube sampling may extract a sample with overall uniform distribution and divide the sample into equal probability sections. Therefore, the latin hypercube sampling may extract relatively consistent and uniform samples.

The first formulation may include, for example, the secondary formation that is an estimate obtained by additional calculation by manuals and/or software using the primary formulation.

The first formulation may include, for example, both the primary formulation and the secondary formulation.

### [Optimization System of Electrolyte for Lithium Secondary Battery]

An optimization system of an electrolyte for a lithium secondary batteries according to another embodiment includes: an evaluator configured to obtain data from a first formulation or a second formulation; a formulation generator configured to obtain the second formulation by applying the first data set including the first formulation and the data obtained from the first formulation to Bayesian Optimization; an updater configured to prepare an updated first data set including an updated first formulation and data obtained from the updated first formulation by updating the first formulation and the data obtained from the first formulation by respectively using the second formulation and the data obtained from the second formulation; and a termination determiner configured to determine whether termination conditions are satisfied. The obtaining of the second formulation, the obtaining of data from the second formulation, and the preparing of the updated first data set are repeated until the termination conditions are satisfied. The data obtained from the first formulation includes first data obtained from an electrolyte prepared by the first formulation and second data obtained from a lithium secondary battery prepared by using the electrolyte. The second data includes a latter retention and a final discharge capacity. In the optimization system for lithium secondary batteries, an electrolyte for lithium secondary batteries with safety and excellent charging and discharging characteristics may be more simply derived by machine learning, for example, Bayesian Optimization.

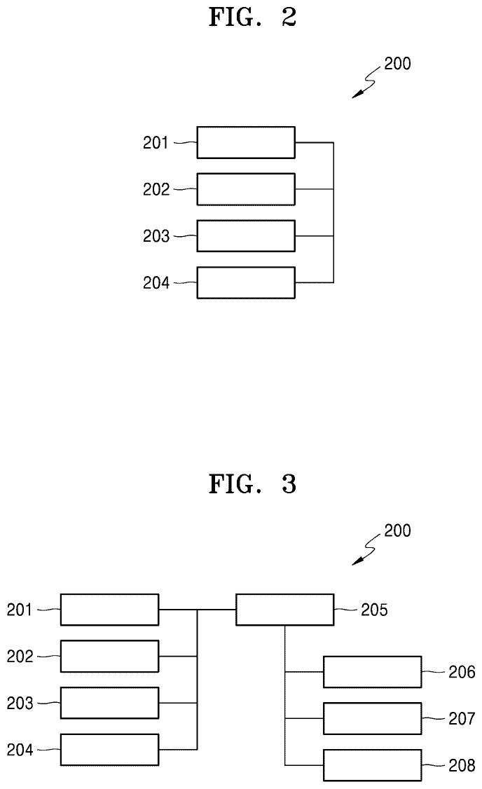

FIG. 2 is a functional block diagram of an optimization system for a lithium secondary battery according to an embodiment. Referring to FIG. 2, an implementation example of the optimization system for a lithium secondary battery will be described.

An optimization system 200 includes an evaluator 201, a formulation generator 202, an updater 203, and a termination determiner 204.

The evaluator 201 obtains data, e.g., a physical property measurement, from the first formulation or the second formulation. The data obtained from the first formulation or the second formulation by the evaluator 201 may include primary data such as a physical property measurement on the first formulation or the second formulation, and a charging and discharging characteristic measurement on the lithium secondary battery including the electrolyte prepared by using the first formulation. The data obtained from the first formulation or the second formulation may include, for example, secondary data that is an estimate obtained by additional calculation by manuals and/or software using the primary data. The data obtained from the first formulation or the second formulation may include, for example, a combination of the primary data and the secondary data.

The evaluator 201, for example, prepares an electrolyte by using the first formulation or the second formulation, obtains first data of the prepared electrolyte, prepares a lithium secondary battery by using the electrolyte, and obtains second data of the prepared lithium secondary battery. The evaluator 201, for example, prepares an electrolyte by using the first formulation or the second formulation, obtains a first physical property measurement of the prepared electrolyte, prepares a lithium secondary battery by using the electrolyte, and obtain a second physical property measurement of the prepared lithium secondary battery. The second data, e.g., the second physical property measurement, includes a latter retention and a final discharge capacity. The evaluator 201 includes an electrolyte manufacturing device, a lithium secondary battery manufacturing device, a first data acquiring device, e.g., first physical property measuring device, and a second data acquiring device, e.g., second physical property measuring device to obtain the first data, e.g., the first physical property measurement, from the electrolyte and the second data, e.g., the second physical property measurement, from the lithium secondary battery. The evaluator 201 may further include a transfer device and a decomposition device.

The formulation generator 202 generates the second formulation, for example, by applying the first data set including the first formulation and the data obtained from the first formulation, e.g., physical property measurement, to Bayesian Optimization.

The updater 203 prepares the updated first data set including the updated first formulation and the updated data obtained from the first formulation, for example, by updating the first formulation and the data obtained from the first formulation by respectively using the second formulation and the data obtained from the second formulation. The evaluator 201 obtains data on the second formulation by using the second formulation generated by the formulation generator 202. The first formulation and the data obtained from the first formulation are updated respectively using the second formulation generated by the formulation generator 202 and data of the second formulation obtained by the evaluator 201. As a result, the updated first data set including the updated first formulation and the data obtained from the updated first formulation is prepared.

The termination determiner 204 determines whether to repeat the obtaining of the second formulation, the obtaining of data from the second formulation, and the preparing of the updated first data set based on the result of determination that the termination conditions are satisfied.

Unless the termination conditions are satisfied, the obtaining of the second formulation, the obtaining of data from the second formulation, and the preparing of the updated first data set are repeated.

FIG. 3 is a functional block diagram of an optimization system for a lithium secondary battery according to another embodiment. Referring to FIG. 3, an implementation example of the optimization system for a lithium secondary battery will be described.

An optimization system 200 includes an evaluator 201, a formulation generator 202, an updater 203, and a termination determiner 204, and further includes a controller 205, a memory 206, an input unit 207, and an output unit 208.

The controller 205 controls each of the elements to realize the function of the optimization system 200.

The controller 205 includes, for example, a memory 206. The memory 206 includes, for example, a memory device. The memory 206 stores, for example, programs, measurement methods, measured data, and the like.

The input unit 207 includes an input device 303. The input device 303 may be a keyboard, a mouse, a scanner, a touch panel, or the like. The output unit 208 includes an output device, such as a liquid crystal display and an organic electro luminescence (EL) display. input unit 207 may be integrated with the output unit 208.

The controller 205 controls the input unit 207 and the output unit 208. For example, the controller 205 may store a formulation input by a user via the input unit 207 in the memory 205 or display a physical property measurement stored in the memory 205 or a data set updated by the updater 203 to the user via the output unit 208.

The functions of the evaluator 201, the formulation generator 202, the updater 203, and the termination determiner 204 are as described above.

For example, the formulation generator 202 generates a new formulation as the controller 205 executes a program stored in the memory 205. The formulation generator 202 generates a new second formulation by applying the first data set including the first formulation and the data obtained from the first formulation to Bayesian Optimization by the program executed by the controller 205.

For example, the updater 203 updates the first data set including the first formulation and the data obtained from the first formulation as the controller 205 executes a program stored in the memory 205. The updater 203 prepares the updated first formulation by updating the first formulation using the second formulation by the program executed by the controller 205. In addition, an electrolyte is prepared by using the updated first formulation, first data is obtained from the prepared electrolyte, a lithium secondary battery is prepared by using the electrolyte, and second data is obtained from the prepared lithium secondary battery. As a result, the first data set is updated to prepare the updated first data set.

The termination determiner 204 determines whether termination conditions are satisfied as the controller 205 executes a program stored in the memory 205. Unless the termination conditions are satisfied, the obtaining of the second formulation, the obtaining of data from the second formulation, and the preparing of the updated first data set are repeated. If the termination conditions are satisfied, the repetition is terminated.

In the optimization system of an electrolyte for lithium secondary batteries, the latter retention is, for example, a ratio Cf/Ca of a final discharge capacity Cf at the last cycle to a latter discharge capacity Ca at a cycle over 20% of the total number of cycles from the first cycle.

The latter discharge capacity may be a discharge capacity at a cycle, for example, over 30% or more, 50% or more, 60% or more, 70% or more, 80% or more, or 90% or more of the total number of cycles from the first cycle.

A latter retention of the lithium secondary battery prepared by using the electrolyte prepared by using the formulation derived by the optimization method of an electrolyte for lithium secondary batteries may be, for example, 90% or more, 91% or more, 92% or more, or 93% or more.

In the optimization system of an electrolyte for lithium secondary batteries, the final discharge capacity Cf is a discharge capacity at the last cycle while the retention is measured.

The final discharge capacity of the lithium secondary battery prepared by using the electrolyte prepared by using the formulation derived by the optimization system of an electrolyte for lithium secondary batteries may be, for example, 148 mAh/g or more, 150 mAh/g or more, 155 mAh/g or more, or 160 mAh/g or more.

In the optimization system of an electrolyte for lithium secondary batteries, the second data may further include, for example, a retention.

The retention is, for example, a ratio Cf/Ci of a discharge capacity Cf at the last cycle to a discharge capacity Ci of the first cycle.

A retention of the lithium secondary battery prepared by using the electrolyte prepared by using the formulation derived by the optimization system of an electrolyte for lithium secondary batteries may be, for example, 80% or more, 81% or more, 82% or more, or 83% or more.

In the optimization system of an electrolyte for lithium secondary batteries, the second data may further include, for example, cumulative discharge capacity over cycle (CDCC). The cumulative discharge capacity of the lithium secondary battery prepared by using the electrolyte prepared by using the formulation derived by the optimization system of an electrolyte for lithium secondary batteries is a sum of discharge capacities of the cycles from the first cycle to the last cycle in the charging and discharging cycles.

In the optimization system of an electrolyte for lithium secondary batteries, the first data may include, for example, self-extinguishing time.

The self-extinguishing time is a time taken for ignition to end after ignition of the electrolyte.

A self-extinguishing time of the electrolyte prepared by using the formulation derived by the optimization system of an electrolyte for lithium secondary batteries may be, for example, 6 sec/g or less, 5 sec/g or less, 4 sec/g or less, 3 sec/g or less, 2 sec/g or less, or 1 sec/g or less.

In the optimization system of an electrolyte for lithium secondary batteries, the first data may further include ionic conductivity. Although ionic conductivity of the electrolyte has a relatively low correlation with the charging and discharging characteristics of the lithium secondary battery, the ionic conductivity may be used as auxiliary physical property data.

[Optimization Apparatus of Electrolyte for Lithium Secondary Battery]

An optimization apparatus of an electrolyte for lithium secondary batteries according to another embodiment includes a data acquiring device configured to obtain data from the first formulation or the second formulation; a computer hardware processor; and a storage medium to store processor-executable instructions. When the processor-executable instructions are executed by the computer hardware processor, the computer hardware processor obtains data from the first formulation by using the data acquiring device, obtains the second formulation by applying the first data set including the first formulation and the data obtained from the first formulation to Bayesian Optimization, obtains data from the second formulation by using the data acquiring device, prepares the updated first data set including the updated first formulation and the data obtained from the updated first formulation by updating the first formulation and the data obtained from the first formulation by respectively using the second formulation and the data obtained from the second formulation, and determines whether termination conditions are satisfied, wherein the obtaining of the second formulation, the obtaining of data from the second formulation, and the preparing of the updated first data set are repeated until the termination conditions are satisfied. The data obtained from the first formulation includes first data obtained from the electrolyte prepared by the first formulation and second data obtained from the lithium secondary battery prepared by using the electrolyte, and the second data includes at least one of a latter retention and a final discharge capacity. In the optimization apparatus for a lithium secondary battery, an electrolyte for lithium secondary batteries with safety and excellent charging and discharging characteristics may be derived more simply by machine learning, for example, Bayesian Optimization.

FIG. 4 is a block diagram of an optimization apparatus for a lithium secondary battery according to another embodiment. Referring to FIG. 4, an implementation example of the optimization apparatus for a lithium secondary battery will be described.

An optimization apparatus 300 includes a data acquiring device 301, a computer hardware processor 302, and a storage medium 303.

The data acquiring device 301 obtains data, e.g., a physical property measurement, from the first formulation or the second formulation. In the data acquiring device 301, the data obtained from the first formulation or the second formulation may include, for example, primary data such as a physical property measurement on the first formulation or the second formulation, and a charging and discharging characteristic measurement on the lithium secondary battery including the electrolyte prepared by using the first formulation. The data obtained from the first formulation or the second formulation may include, for example, secondary data that is an estimate obtained by additional calculation by manuals and/or software using the primary data. The data obtained from the first formulation or the second formulation may include, for example, a combination of the primary data and the secondary data.

The data acquiring device 301, for example, prepares an electrolyte by using the first formulation or the second formulation, obtains first data from the prepared electrolyte, prepares a lithium secondary battery by using the electrolyte, and obtains second data of the prepared lithium secondary battery. The data acquiring device 301, for example, prepares an electrolyte by using the first formulation or the second formulation, obtains a first physical property measurement from the prepared electrolyte, prepares a lithium secondary battery by using the electrolyte, and obtains a second physical property measurement from the prepared lithium secondary battery. The second data, for example, the second physical property measurement, includes a latter retention and a final discharge capacity. The data acquiring device 301 includes an electrolyte manufacturing device, a lithium secondary battery manufacturing device, a first data acquiring device, e.g., first physical property measuring device, and a second data acquiring device, e.g., second physical property measuring device to obtain the first data, e.g., the first physical property measurement, from the electrolyte and the second data, e.g., the second physical property measurement, from the lithium secondary battery. The data acquiring device 301 may further include a transfer device and a decomposition device.

The computer hardware processor 302 may control writing data to and reading data from the memory 304 and a non-volatile storage medium 305. The computer hardware processor 302 may be, for example, a microprocessor, a processor core, a multiprocessor, an application-specific integrated circuit (ASIC).

The storage medium 303 includes, for example, a memory 304 and a non-volatile storage medium 305. The storage medium 303 may be, for example, Read Only Memory (ROM), Random Access Memory (RAM), Hard Disk Dive (HDD), or a flash memory. The storage medium 303 stores processor-executable instructions.

The processor-executable instructions are executed by the computer hardware processor 302.

By executing the processor-executable instructions, the computer hardware processor 302 obtains data, e.g., physical property measurement, from the first formulation by using the data acquiring device, obtains the second formulation by applying the first data set including the first formulation and the data obtained from the first formulation to Bayesian Optimization, obtains data from the second formulation by using the data acquiring device, prepares the updated first data set including the updated first formulation and the data obtained from the updated first formulation by updating the first formulation and the data obtained from the first formulation by respectively using the second formulation and the data obtained from the second formulation, and determines whether termination conditions are satisfied. In addition, the computer hardware processor 302 repeats the obtaining of the second formulation, the obtaining of data from the second formulation, and the preparing of the updated first data set until the termination conditions are satisfied.

In the optimization apparatus of an electrolyte for lithium secondary batteries, the latter retention is, for example, a ratio Cf/Ca of a final discharge capacity Cf at the last cycle to a latter discharge capacity Ca at a cycle over 20% of the total number of cycles from the first cycle.

The latter discharge capacity may be a discharge capacity at a cycle, for example, over 30% or more, 50% or more, 60% or more, 70% or more, 80% or more, or 90% or more of the total number of cycles from the first cycle.

The latter retention of the lithium secondary battery prepared by using the electrolyte prepared by using the formulation derived by the optimization apparatus of an electrolyte for lithium secondary batteries may be, for example, 90% or more, 91% or more, 92% or more, or 93% or more.

In the optimization apparatus of an electrolyte for lithium secondary batteries, the final discharge capacity Cf is a discharge capacity at the last cycle while the retention is measured.

The final discharge capacity of the lithium secondary battery prepared by using the electrolyte prepared by using the formulation derived by the optimization apparatus of an electrolyte for lithium secondary batteries may be, for example, 148 mAh/g or more, 150 mAh/g or more, 155 mAh/g or more, or 160 mAh/g or more.

In the optimization apparatus of an electrolyte for lithium secondary batteries, the second data may further include, for example, a retention.

The retention is, for example, a ratio Cf/Ci of a discharge capacity Cf at the last cycle to a discharge capacity Ci of the first cycle.

A retention of the lithium secondary battery prepared by using the electrolyte prepared by using the formulation derived by the optimization apparatus of an electrolyte for lithium secondary batteries may be, for example, 80% or more, 81% or more, 82% or more, or 83% or more.

In the optimization apparatus of an electrolyte for lithium secondary batteries, the second data may further include, for example, cumulative discharge capacity over cycle (CDCC). The cumulative discharge capacity of the lithium secondary battery prepared by using the electrolyte prepared by using the formulation derived by the optimization apparatus of an electrolyte for lithium secondary batteries is a sum of discharge capacities of the cycles from the first cycle to the last cycle in the charging and discharging cycles.

In the optimization apparatus of an electrolyte for lithium secondary batteries, the first data may include, for example, self-extinguishing time.

The self-extinguishing time is a time taken for ignition to end after ignition of the electrolyte.

The self-extinguishing time of the electrolyte by using the formulation derived by the optimization apparatus of an electrolyte for lithium secondary batteries may be, for example, 6 sec/g or less, 5 sec/g or less, 4 sec/g or less, 3 sec/g or less, 2 sec/g or less, or 1 sec/g or less.

In the optimization apparatus of an electrolyte for lithium secondary batteries, the first data may further include ionic conductivity. Although ionic conductivity of the electrolyte has a relatively low correlation with the charging and discharging characteristics of the lithium secondary battery, the ionic conductivity may be used as auxiliary physical property data.

[Electrolyte for Lithium Secondary Battery]

An electrolyte for lithium secondary batteries according to another embodiment is prepared from a formulation obtained by the above-described optimization method of an electrolyte for lithium secondary batteries.

The electrolyte prepared from the formulation obtained by the optimization method of an electrolyte for lithium secondary batteries provides safety and excellent charging and discharging characteristics.

The electrolyte may include, for example, a cyclic carbonate solvent, a fluorine-containing ester solvent, an additive, and a lithium salt.

The cyclic carbonate solvent may be, for example, a compound represented by Formula 1 below.

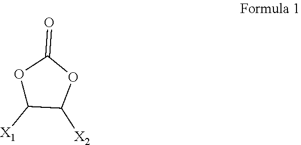

In Formula 1,

X₁ and X₂ are each independently hydrogen, a halogen atom, a C1-C10 alkyl group unsubstituted or substituted with a halogen atom, a C2-C10 alkenyl group unsubstituted or substituted with a halogen atom, a C2-C10 alkynyl group unsubstituted or substituted with a halogen atom, a C4-C10 aryl group unsubstituted or substituted with a halogen atom, or a C2-C10 heteroaryl group unsubstituted or substituted with a halogen atom.

The cyclic carbonate solvent may be, for example, ethylene carbonate (EC), propylene carbonate (PC), fluoroethylene carbonate (FEC), 4,4-difluoroethylene carbonate, 4,5-difluoroethylene carbonate, 4-methyl-5-fluoroethylene carbonate, 4-methyl-5,5-difluoroethylene carbonate, 4-(fluoromethyl)ethylene carbonate, 4-(difluoromethyl)ethylene carbonate, 4-(trifluoromethyl)ethylene carbonate, 4-(2-fluoroethyl)ethylene carbonate, 4-(2,2-difluoroethyl)ethylene carbonate, 4-(2,2,2-trifluoroethyl)ethylene carbonate, 4,5-dimethylethylene carbonate, and any combination thereof. The cyclic carbonate solvent may be, for example, propylene carbonate (PC).

The fluorine-containing ester solvent may be, for example, a compound represented by Formula 2 below.

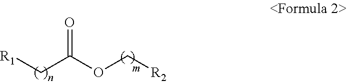

In Formula 2,

R₁ and R₂ are each independently hydrogen, a C1-C10 alkyl group unsubstituted or substituted with a halogen atom, a C2-C10 alkenyl group unsubstituted or substituted with a halogen atom, a C2-C10 alkynyl group unsubstituted or substituted with a halogen atom, a C4-C10 aryl group unsubstituted or substituted with a halogen atom, or a C2-C10 hetoroaryl group unsubstituted or substituted with a halogen atom, and n and m are each independently 0 to 5.

The fluorine-containing ester solvent may be, for example, fluoromethylacetate, difluoromethylacetate, trifluoromethylacetate, 2-fluoroethylacetate, 2,2-difluoroethyl acetate, 2,2,2-trifluoroethylacetate, fluoromethylpropionate, difluoromethylpropionate, trifluoromethyl propionate, 2-fluoroethyl propionate, 2,2-difluoroethyl propionate, 2,2,2-trifluoroethyl propionate, 2-fluoroethyl butylate, 2,2-difluoroethyl butylate, 2,2,2-trifluoroethyl butylate (TFEB), and any combination thereof. The fluorine-containing ester solvent may be, for example, 2,2,2-trifluoroethyl acetate (TFEA) or 2,2,2-trifluoroethyl propionate (TFEP).

A content ratio of the cyclic carbonate solvent to the fluorine-containing ester solvent may be 10:90 to 50:50, 20:80 to 50:50, 20:80 to 40:60, 25:75 to 40:60, or 25:70 to 35:65. The content ratio may be a volume ratio.

The additive may include, for example, vinylene carbonate (VC), vinylene ethylene carbonate (VEC), propane sultone (PS), fluoroethylene carbonate (FEC), ethylene sulfate (ES), lithium fluorophosphate (LiPO₂F₂), lithium oxalyldifluoroborate (LiODFB), lithium bis(oxalato) borate (LiBOB), or any combination thereof, but is not limited thereto, and any compound available in the art as an additive may also be used.

The amount of the additive may be 2 wt % to 10 wt %, 2 wt % to 5 wt %, or 2 wt % to 4 wt % based on a total weight of the electrolyte.

The lithium salt may include, for example, LiPF₆, LiClO₄, LiBF₄, LiAlO₄, LiAlCl₄, LiCF₃SO₃, LiC₄F₉SO₃, LiC₆H₅SO₃, LiN(C₂F₅SO₃)₂, LiN(C₂F₅SO₂)₂, LiN(CF₃SO₂)₂, LiN(FSO₂)₂, LiN(CₓF₂ₓ₊₁SO₂)(C_{y}F_{2y+1}SO₂) (wherein x and y are 0 or a natural number), LiCl, LiI, LiSCN, LIB (C₂O₄)₂, LiF₂BC₂O₄, LiPF₄(C₂O₄), LiPF₂(C₂O₄)₂, LiPO₂F₂, LiP(C₂O₄)₃, or any combination thereof.

The amount of the lithium salt may be 0.1 M to 1 M, 0.5 M to 5 M, or 0.5 M to 2 M.

In the electrolyte prepared according to the formulation obtained by the optimization method of an electrolyte for lithium secondary batteries, for example, the cyclic carbonate solvent may be mixed with the fluorine-containing ester solvent in a volume ratio of 25:70 to 35:65, the amount of the additive may be 2 wt % to 4 wt %, and the concentration of the lithium salt may be 0.5 M to 2 M.

### [Lithium Secondary Battery]

A lithium secondary battery according to another embodiment includes the above-described electrolyte.

For example, the lithium secondary battery may be prepared according to the following method.

First, a positive electrode is prepared.

For example, a positive active material, a conductive material, a binder, and a solvent are mixed to prepare a positive active material composition. The positive active material composition is directly coated on a metal current collector to prepare a positive electrode plate. Alternatively, the positive active material composition is cast on a separate support, and then a film separated from the support is laminated on the metal current collect to prepare a positive electrode plate. However, the positive electrode is not limited thereto and may have any other shape.

The positive active material may be any lithium-containing metal oxide commonly used in the art without limitation. For example, the lithium-containing metal oxide may include at least one composite oxide of lithium and a metal selected from cobalt, manganese, nickel, and any combination thereof. The lithium-containing metal oxide may include, for example, a compound represented by any one of the following formulae: LiₐA_{1-b}B′_{b}D₂ (wherein 0.90≤a≤1 and 0≤b≤0.5); LiₐE_{1-b}B′_{b}O_{2-c}D_{c} (wherein 0.90≤a≤1, 0≤b≤0.5, and 0≤c≤0.05); LiE_{2-b}B′_{b}O_{4-c}D_{c} (wherein 0≤b≤0.5 and 0≤c≤0.05); LiₐNi_{1-b-c}Co_{b}B′_{c}D_{α} (wherein 0.90≤a≤1, 0≤b≤0.5, 0≤c≤0.05, and 0<α≤2); LiₐNi_{1-b-c}Co_{b}B′_{c}O_{2-α}F′_{α} (wherein 0.90≤a≤1, 0≤b≤0.5, 0≤c≤0.05, and 0<α<2); LiₐNi_{1-b-c}Mn_{b}B′_{c}D_{α} (wherein 0.90≤a≤1, 0≤b≤0.5, 0≤c≤0.05, and 0<α≤2); LiₐNi_{1-b-c}Mn_{b}B′_{c}O_{2-α}F′_{α} (wherein 0.90≤a≤1, 0≤b≤0.5, 0≤c≤0.05, and 0<α<2); LiₐNi_{b}E_{c}G_{d}O₂ (wherein 0.90≤a≤1, 0≤b≤0.9, 0≤c≤0.5, and 0.001≤d≤0.1); LiₐNi_{b}Co_{c}Mn_{d}GₑO₂ (wherein 0.90≤a≤1, 0≤b≤0.9, 0≤c≤0.5, 0≤d≤0.5, and 0≤e≤0.1); LiₐNiG_{b}O₂ (wherein 0.90≤a≤1 and 0.001≤b≤0.1); LiₐCoG_{b}O₂ (wherein 0.90≤a≤1 and 0.001≤b≤0.1); LiₐMnG_{b}O₂ (wherein 0.90≤a≤1 and 0.001≤b≤0.1); LiₐMn_{2-b}A_{c}O₄ (wherein 0.90≤a≤ 1, 0.01≤b≤0.5, and 0.001≤c≤0.1); LiV₂O₅; LiI′O₂; LiNiVO₄; Li_{(3-f)}J₂(PO₄)₃ (wherein 0≤ f≤2); Li_{(3-f)}Fe₂ (PO₄)₃ (wherein 0≤f≤2); LiFePO₄; and LiFe₁₋ₐMnₐPO₄ (wherein 0.01≤a≤0.7).

In the formulae representing compounds above, A is Ni, Co, Mn, or any combination thereof; B′ is Al, Ni, Co, Mn, Cr, Fe, Mg, Sr, V, a rare earth element, or any combination thereof; D is O, F, S, P, or any combination thereof; E is Co, Mn, or any combination thereof; F′ is F, S, P, or any combination thereof; G is Al, Cr, Mn, Fe, Mg, La, Ce, Sr, V, or any combination thereof; Q is Ti, Mo, Mn, or any combination thereof; l′ is Cr, V, Fe, Sc, Y, or any combination thereof; and J is V, Cr, Mn, Co, Ni, Cu, or any combination thereof. The above-described compound having a coating layer on the surface thereof may also be used or a mixture of the above-described compound and a compound having a coating layer may also be used. The coating layer added to the surface of the compound may include, for example, a compound of a coating element such as an oxide, hydroxide, oxyhydroxide, oxycarbonate, or hydroxycarbonate of the coating element. The compound constituting the coating layer may be amorphous or crystalline. The coating element included in the coating layer may be Mg, Al, Co, K, Na, Ca, Si, Ti, V, Sn, Ge, Ga, B, As, Zr, or any mixture thereof. A method of forming the coating layer may be selected from those not adversely affecting physical properties of the positive active material. The coating methods may be, for example, spray coating and dip coating. These methods may be obvious to those of ordinary skill in the art, and thus detailed descriptions thereof will not be given.

The conductive material may be carbon black, graphite particulates, and the like, but is not limited to, and any material commonly used in the art as conductive materials may also be used.

The binder may be a vinylidene fluoride/hexafluoropropylene copolymer, polyvinylidene fluoride (PVDF), polyacrylonitrile, polymethylmethacrylate, polytetrafluoroethylene and a mixture thereof, or a styrene butadiene rubber polymer, but is not limited thereto, and any material commonly used in the art as binders may also be used.

For example, the binder may be a non-aqueous binder identical to a polymer layer of a separator or a binder identical to an aqueous binder of the positive electrode.

The solvent may be N-methylpyrrolidone (NMP), acetone, and water, but is not limited thereto, and any solvent commonly used in the art may also be used.

Contents of the positive active material, the conductive material, the binder, and the solvent are the same levels as those commonly used in lithium batteries. At least one of the conductive material, the binder, and the solvent may be omitted in accordance with a use and a configuration of the lithium battery.

Next, a negative electrode is prepared.

For example, a negative active material, a conductive material, two or more aqueous binders, and a solvent are mixed to prepare a negative active material composition. The negative active material composition is directly coated on a metal current collector to prepare a negative electrode plate. Alternatively, the negative active material composition is cast on a separate support, and then a film separated from the support is laminated on a metal current collect to prepare a negative electrode plate.

The negative active material may be a carbonaceous material as described above, but is not limited thereto The negative active material may be any material commonly used in the art as negative active materials of lithium batteries. For example, the negative active material may include at least one selected from lithium metal, a metal alloyable with lithium, a transition metal oxide, a non-transition metal oxide, silicon, and a carbonaceous material.

For example, the metal alloyable with lithium may be Si, Sn, Al, Ge, Pb, Bi, Sb, an Si—Y alloy (wherein Y is an alkali metal, an alkali earth metal, a Group XIII element, a Group XIV element, a transition metal, a rare earth element, or any combination thereof, except for Si), an Sn—Y alloy (wherein Y is an alkali metal, an alkali earth metal, a Group XIII element, a Group XIV element, a transition metal, a rare earth element, or any combination thereof, except for Sn), and the like. The element Y may be Mg, Ca, Sr, Ba, Ra, Sc, Y, Ti, Zr, Hf, Rf, V, Nb, Ta, Db, Cr, Mo, W, Sg, Tc, Re, Bh, Fe, Pb, Ru, Os, Hs, Rh, Ir, Pd, Pt, Cu, Ag, Au, Zn, Cd, B, Al, Ga, Sn, In, Ti, Ge, P, As, Sb, Bi, S, Se, Te, Po, or any combination thereof.

For example, the transition metal oxide may be a lithium titanium oxide, a vanadium oxide, a lithium vanadium oxide, or the like.

For example, the non-transition metal oxide may be SnO₂, SiOₓ (wherein 0<x<2), or the like.

The conductive material in the negative active material composition may be the same as that of the positive active material composition. In the negative active material composition, the binder includes the above-described two or more aqueous binders, and the solvent is water. Meanwhile, a plasticizer may further be added to the positive active material composition and/or the negative active material composition to form pores in the electrode plates.

Contents of the negative active material, the conductive material, the binder, and the solvent are the same as those commonly used in lithium batteries. At least one of the conductive material, the binder, and the solvent may be omitted in accordance with a use and a configuration of the lithium battery.

Subsequently, a separator to be inserted between the positive electrode and the negative electrode is prepared.

Any separator commonly used in the art for lithium batteries may be used. For example, any separator having low resistance to ion migration of the electrolyte and excellent electrolyte-retaining ability may be used. For example, the separator may be selected from glass fiber, polyester, Teflon, polyethylene, polypropylene, polytetrafluoroethylene (PTFE), or any combination thereof, each of which is a non-woven or woven fabric. For example, a windable separator including polyethylene or polypropylene may be used in lithium-ion batteries and a separator having excellent organic electrolyte-retaining ability may be used in lithium-ion polymer batteries.

The separator may be prepared according to the following exemplary method. However, the method is not limited thereto and adjusted according to required conditions.

First, a polymer resin, a filler, and a solvent may be mixed to prepare a separator composition. The separator composition may directly be applied onto an electrode and dried to prepare a separator. Alternatively, the separator composition is cast on a support and dried and then a separator film separated from the support is laminated on an electrode to form a separator.

The polymer used to prepare the separator is not limited and any polymer commonly used as a binder for electrode plates may also be used. For example, a vinylidene fluoride/hexafluoropropylene copolymer, polyvinylidenefluoride (PVDF), polyacrylonitrile, polymethylmethacrylate, or any mixture thereof may be used.

Subsequently, an electrolyte may be prepared.

The electrolyte may be the above-described electrolyte.

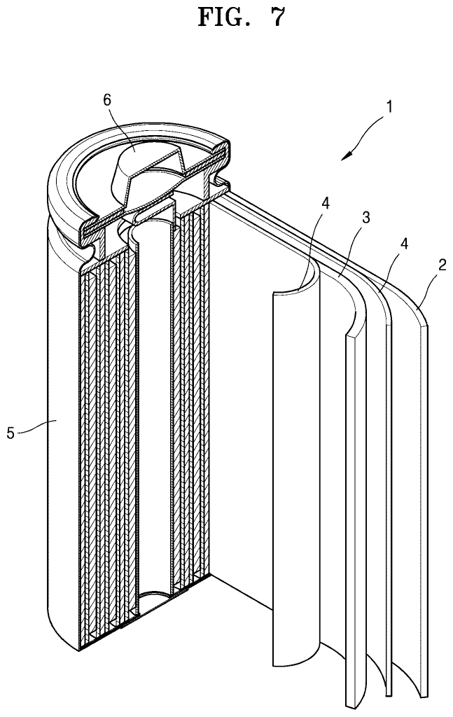

As shown in FIG. 7, the lithium secondary battery 1 includes a positive electrode 3, a negative electrode 2, and a separator 4. The positive electrode 3, the negative electrode 2, and the separator 4 are wound or folded and accommodated in a battery case 5. Then, an electrolyte is injected into the battery case 5 and the battery case 5 is sealed with a cap assembly 6 to complete preparation of the lithium battery 1. The battery case 5 may be a cylindrical type, a rectangular type, or a thin film type. For example, the lithium secondary battery may be a thin film type battery. The lithium secondary battery may be a lithium ion battery.

The separator may be disposed between the positive electrode and the negative electrode to form a battery assembly. The battery assembly may be stacked in a bi-cell structure, impregnated with an electrolyte, accommodated in a pouch, and sealed to complete preparation of the lithium ion polymer battery.

In addition, a plurality of the battery assemblies may be stacked to form a battery pack which may be used in any devices that require high capacity and high output. For example, battery packs may be used in laptop computers, smart phones, and electric vehicles (EVs).

As used herein, the substituent may be derived by substitution of at least one hydrogen atom in an unsubstituted mother group with another atom or a functional group. Unless stated otherwise, a “substituted” functional group refers to a functional group substituted with at least one substituent selected from a C1-C40 alkyl group, a C₂-C₄₀ alkenyl group, a C₂-C₄₀ alkynyl group, a C3-C40 cycloalkyl group, a C3-C40 cycloalkenyl group, and a C7-C40 aryl group. When a functional group is “optionally” substituted, it means that the functional group may be substituted with such a substituent as listed above.

Throughout the specification, a and b of the term “Ca-Cb” refer to the numbers of carbon atoms of a particular functional group. That is, the functional group may include a to b carbon atoms. For example, a “C₁-C₄ alkyl group” refers to an alkyl group including 1 to 4 carbon atoms, i.e., CH₃—, CH₃CH₂—, CH₃CH₂CH₂—, (CH₃)₂CH—, CH₃CH₂CH₂CH₂—, CH₃CH₂CH(CH₃)— and (CH₃)₃C—.

A nomenclature for a particular functional group may include mono-radical or di-radical depending on the context. For example, when a substituent requires two linkages to the rest of the molecule, the substituent should be understood as a diradical. For example, a substituent specified as an alkyl group requiring two linkages includes a diradical, such as —CH₂—, —CH₂CH₂—, —CH₂CH(CH₃)CH₂—, and the like. Another nomenclature for other radicals, such as “alkylene” clearly indicates that the radical is a diradical.

As used herein, the term “alkyl group” or “alkylene group” refers to a branched or unbranched aliphatic hydrocarbon group. In an embodiment, the alkyl group may be substituted or unsubstituted. Examples of the alkyl group are a methyl group, an ethyl group, a propyl group, an isopropyl group, a butyl group, an isobutyl group, a tert-butyl group, a pentyl group, a hexyl group, a cyclopropyl group, a cyclopentyl group, a cyclohexyl group, a cycloheptyl group, and the like, but are not limited thereto, and each of the substituents may be optionally substituted or unsubstituted. In an embodiment, the alkyl group may include 1 to 6 carbon atoms. Examples of the C₁-C₆ alkyl group include methyl, ethyl, propyl, isopropyl, butyl, iso-butyl, sec-butyl, pentyl, 3-pentyl, hexyl, and the like, but are not limited thereto.

As used herein, the term “alkenyl group”, as a hydrocarbon group including 2 to 20 carbon atoms with at least one carbon-carbon double bond, may include an ethenyl group, a 1-propenyl group, a 2-propenyl group, a 2-methyl-1-propenyl group, a 1-butenyl group, a 2-butenyl group, a cyclopropenyl group, a cyclopentenyl group, a cyclohexenyl group, a cycloheptenyl group, and the like, but is not limited thereto. In an embodiment, the alkenyl group may be substituted or unsubstituted. In an embodiment, the alkenyl group may include 2 to 40 carbon atoms.

As used herein, the term “alkynyl group”, as a hydrocarbon group including 2 to 20 carbon atoms with at least one carbon-carbon triple bond, may include en ethynyl group, a 1-propynyl group, a 1-butynyl group, a 2-butynyl group, and the like, but is not limited thereto. In an embodiment, the alkynyl group may be substituted or unsubstituted. In an embodiment, the alkynyl group may have 2 to 40 carbon atoms.

As used herein, the term “aromatic” refers to a ring or ring system having a conjugated pi electron system, and includes a carbocyclic aromatic group (e.g., a phenyl group) and a heterocyclic aromatic group (e.g., pyridine). The term includes a monocyclic or fused polycyclic ring (i.e., a ring that shares adjacent pairs of atoms) as long as the entire ring system is aromatic.

As used herein, the term “aryl group” refers to an aromatic ring or ring system (that is, a fused ring of at least two rings sharing two adjacent carbon atoms) in which the ring backbone includes only carbon, or a linked ring of two or more aromatic rings via a single bond. When the aryl group is a ring system, each ring in the system is aromatic. For example, the aryl group may include a phenyl group, a biphenyl group, a naphthyl group, a phenanthrenyl group, a naphthacenyl group, and the like, but is not limited thereto. The aryl group may be substituted or unsubstituted.

As used herein, the term “halogen” refers to a stable atom belonging to Group 17 of the periodic table of elements, for example, fluorine, chlorine, bromine, or iodine, particularly, fluorine and/or chlorine.

Hereinafter, the disclosure will be described in more detail with reference to the following examples and comparative examples. However, these examples are not intended to limit the purpose and scope of the one or more embodiments.

### (Preparation of First Formulation)

### Preparation Example 1: Preparation of Electrolyte for Secondary Battery

A mixed solvent was prepared by using propylene carbonate (PC) as a cyclic carbonate solvent and a fluorine-containing ester solvent 2,2,2-trifluoroethyl acetate (TFA) as an acyclic solvent.

As the additive, fluoroethylene carbonate (FEC) that is a fluorine-containing cyclic carbonate or vinylene carbonate (VC) that is fluorine-free cyclic carbonate was used.

LiPF₆ was used as the lithium salt, and the concentration of the lithium salt was 1 M. A content of the additive is an amount of the additive based on a total weight of the electrolyte. A content of propylene carbonate (PC) in the solvent is a volume of propylene carbonate based on a total volume of the solvent.

Electrolyte samples having 15 compositions below were derived by combining the content of propylene carbonate (PC) in the solvent, types of additive, and content of the additive. The compositions of the samples are shown in Table 1 below.

TABLE 1

| First | Content of PC in | Type of | Content of additive |
|---|---|---|---|
| formulation | solvent [vol. %] | additive | [wt. %] |
| Sample 1 | 30.0 | — | — |
| Sample 2 | 0.0 | — | — |
| Sample 3 | 10.0 | — | — |
| Sample 4 | 20.0 | — | — |
| Sample 5 | 40.0 | — | — |
| Sample 6 | 30.0 | VC | 1.0 |
| Sample 7 | 30.0 | VC | 2.0 |
| Sample 8 | 30.0 | FEC | 1.0 |
| Sample 9 | 30.0 | FEC | 2.0 |
| Sample 10 | 37.0 | FEC | 3.0 |
| Sample 11 | 40.0 | VC | 3.0 |
| Sample 12 | 39.0 | FEC | 3.0 |
| Sample 13 | 28.0 | FEC | 3.0 |
| Sample 14 | 26.0 | VC | 3.0 |
| Sample 15 | 25.0 | FEC | 3.0 |

### Preparation Example 2: Preparation of Lithium Secondary Battery (Half Cell)

### (Preparation of Positive Electrode)

A positive active material slurry was prepared by mixing LiNi_{0.6}Co_{0.2}Mn_{0.2}O₂ as a positive active material, a carbonaceous conductive material (Super P), and polyvinylidene fluoride (PVdF) in a weight ratio of 80:10:10 in an agate mortar together with N-methylpyrrolidone (NMP).

The prepared slurry was applied to an Al current collector and dried to prepare a positive electrode.

### (Preparation of Coin Cell)

Coin cells were prepared by using the positive electrode prepared as described above, lithium metal as a counter electrode, a separator (prepared by coating a ceramic on a polyethylene (PE) substrate), and the electrolytes of Samples 1 to 14 prepared in Preparation Examples 1, respectively.

### Evaluation Example 1: Measurement of Self-Extinguishing Time

Ignition was caused in the electrolytes of Samples 1 to 15 prepared in Preparation Example 1 by using a torch, and self-extinguishing time (second, s) (SET) of the electrolytes per weight (g) after removing the torch was measured.

### Evaluation Example 2: Measurement of Retention, Latter Retention, Final Discharge Capacity

The coin cells prepared in Preparation Example 2 were charged and discharged until 100th cycle at room temperature (25° C.) at a constant current of 1 C rate in a voltage range of 2.5 V to 4.6 V (vs. Li).

The retention and latter retention were calculated according to Equation 1 and 2 below, respectively. Discharge capacity at 1st cycle was referred to as initial discharge capacity, and discharge capacity at 100th cycle was referred to as final discharge capacity. Evaluation results are shown in Table 2 below.

$$Retention ( \% ) = [ discharge capacity at {100}^{th} cycle / discharge capacity at {1}^{st} cycle ] \times 100 \qquad Equation 1$$

$$Letter retention ( \% ) = [ discharge capacity at {50}^{th} cycle / discharge capacity at {36}^{th} cycle ] \times 100 \qquad Equation 2$$

TABLE 2

| First formulation | Latter retention [%] | Retention [%] |
|---|---|---|
| Sample 1 | 97.8 | 79.7 |
| Sample 2 | 75.3 | 4.1 |
| Sample 3 | 79.1 | 16.6 |
| Sample 4 | 97.3 | 47.9 |
| Sample 5 | 96.2 | 72.8 |
| Sample 6 | 95.2 | 72.4 |
| Sample 7 | 96.5 | 80.0 |
| Sample 8 | 95.4 | 75.1 |
| Sample 9 | 97.2 | 81.5 |
| Sample 10 | 94.0 | 70.5 |
| Sample 11 | 94.5 | 97.6 |
| Sample 12 | 94.4 | 67.9 |
| Sample 13 | 96.3 | 79.5 |
| Sample 14 | 95.9 | 74.1 |
| Sample 15 | 96.1 | 78.1 |

### Evaluation Example 3: Evaluation on Correlation Between Latter Retention and Retention

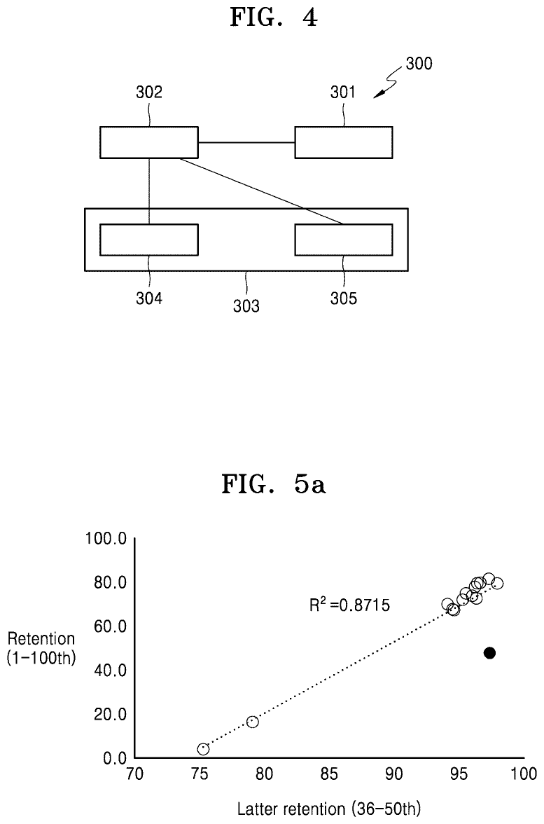

Correlation between retention and latter retention shown in Table 2 of Evaluation Example 2 was evaluated and results are shown in FIGS. 5A and 5B.

As shown in FIG. 5A, when outliers are included, a coefficient of determination (R²) was 0.8715. However, as shown in FIG. 5B, when outliers are excluded, the coefficient of determination (R²) was 0.9919 close to 1.

Therefore, because correlation between the latter retention and the retention was high, it was confirmed that the latter retention may be used as a criterion of the retention.

### Evaluation Example 4: Evaluation on Correlation Between Ionic Conductivity and Retention

Ionic conductivity of the electrolytes of Samples 1 to 9 of Table 1 and lifespan characteristics of coin cells including the electrolytes of Samples 1 to 9 were measured, and results are shown in Table 3.

Ionic conductivity of sample electrolytes was measured by impedance spectroscopy at 25° C. at 1 atm.

TABLE 3

| | Ionic conductivity | |
|---|---|---|
| First formulation | [mS/cm] | Retention [%] |
| Sample 1 | 7.1 | 79.7 |
| Sample 8 | 7.2 | 75.1 |
| Sample 9 | 7.3 | 81.5 |
| Sample 6 | 7.3 | 72.4 |
| Sample 5 | 7.7 | 72.8 |

As shown in Table 3, while Sample 5 having the highest ionic conductivity showed a relatively low retention, Sample 1 having the lowest ionic conductivity showed a relatively high retention. Therefore, it was confirmed that correlation between the ionic conductivity and retention of the electrolyte was low.

### Evaluation Example 5: Comparison Between Initial Discharge Capacity and Final Discharge Capacity

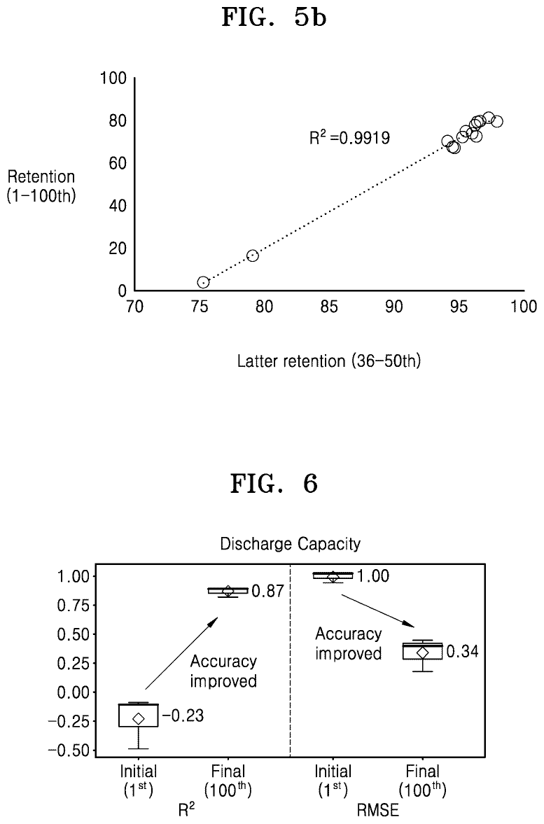

Coefficients of determination (R²) and root mean square errors (RMSE) of initial discharge capacities (discharge capacity at 1st cycle) and final discharge capacities (discharge capacity at 100th cycle) of Samples 1 to 15 measured in Evaluation Example 1 were calculated by the K-fold Cross Validation and results are shown in FIG. 6. A coefficient of determination (R²), as an “absolute value”, closer to 1 indicates better absolute performance prediction. A smaller root mean square error (RMSE), as a “relative value” indicates better relative performance prediction.

As shown in FIG. 6, because the root mean square error (RMSE) of the final discharge capacity is smaller than the root mean square error (RMSE) of the initial discharge capacity, the final discharge capacity exhibits better relative performance prediction.

In addition, because the final discharge capacity had a coefficient of determination of 0.87, close to 1, the final discharge capacity is suitable as an evaluation index for absolute performance prediction. As a result, because the final discharge capacity, rather than the initial discharge capacity, is suitable for relative and absolute performance prediction, it was confirmed that the final discharge capacity is more suitable, as an evaluation index for performance prediction of the lithium secondary battery, than the initial discharge capacity.

As shown in FIG. 6, the root mean square error of the final discharge capacity was far less than the root mean square error of the initial discharge capacity, and thus prediction errors of data decreased.

Therefore, it was confirmed that the final discharge capacity is more suitable for performance prediction of secondary batteries than the initial discharge capacity.

### Evaluation Example 6: Optimization by Experiment

Based on physical property measurement results of Evaluation Examples 1 and 2, Sample 9 having a composition providing excellent final discharge capacity and retention was selected among Samples 1 to 15 prepared in Preparation Example 1.

The composition and physical property measurement of Sample 9 are shown in Table 4 below.

### Evaluation Example 7: Bayesian Optimization

A first data set including a first formulation including Samples 1 to 15 prepared in Preparation Example 1 and physical property measurements (retention, latter retention, final discharge capacity, and self-extinguishing time) of Samples 1 to 15 was prepared.

A second formulation having a maximum value of the objective function was obtained from the first data set via Bayesian Optimization.

An electrolyte of Sample 16 was prepared according to the second formulation in the same manner as in Preparation Example 1, and a coin cell was prepared by using the electrolyte in the same manner as in Preparation Example 2.

Self-extinguishing time, retention, latter retention, and final discharge capacity of the prepared electrolyte and the coin cell were measured according to the methods of Evaluation Example 1 and Evaluation Example 2.

As a result, an updated first data set including an updated first formulation and a physical property measurement obtained from the updated first formulation was prepared.

The updated first formulation includes Samples 1 to 15 and further includes newly added Sample 16, and the updated first data set included the updated first formulation and physical property measurements thereof.

It was determined whether the updated first formulation satisfied termination conditions.

The termination conditions were whether there is a sample providing improved final discharge capacity and retention compared to Sample 9 that is optimized by an experiment.

In the case where the updated first formulation includes a sample satisfying the termination conditions, Bayesian Optimization was terminated.

In the case where the updated first formulation does not include a sample satisfying the termination conditions, the preparation of the updated first data set may be performed again by obtaining a second formulation including a maximum value of the objective function from the updated first data set by Bayesian Optimization, and measuring physical property measurements from an electrode and a coin cell prepared using the obtained second formulation.

Until a sample satisfying the termination conditions is derived, the obtaining of the second formulation, the obtaining of the physical property measurement from the second formulation, and the preparing of the updated first data set may be repeated.

Bayesian Optimization was performed once while modifying the configuration of the objective function. The configuration of the objective function, compositions of samples derived by Bayesian Optimization, and physical property measurements thereof are shown in Table 4 below.

TABLE 4

| | | | Final | |
|---|---|---|---|---|
| | | Composition | discharge | Reten- |
| | Objective | of | capacity | tion |
| | function | electrolyte | [mAh/g] | [%] |
| Optimization | — | PC:TFA = 30:70, | 157.45 | 81.53 |
| of Experiment | | FEC 2 wt. % | | |
| Bayesian | Elc(SET) + | PC:TFA = 33:67, | 136.43 | 76.86 |
| Optimization A | 30Elc(Ret) | FEC 2 wt. % | | |
| Bayesian | Elc(SET) + | PC:TFA = 38:62, | 136.01 | 79.03 |
| Optimization B | 30Elc(Ret) + | FEC 1.5 wt. % | | |
| | 15Elc(Lat) | | | |
| Bayesian | Elc(SET) + | PC:TFA = 31:69, | 160.37 | 83.01 |
| Optimization C | 30Elc(Ret) + | FEC 2.5 wt. % | | |
| | 20Elc(FDC) + | | | |
| | 15Elc(Lat) | | | |

As shown in Table 4, according to Bayesian Optimization C using the objective function including self-extinguishing time, retention, final discharge capacity, and latter retention, the termination conditions were satisfied by performing Bayesian Optimization once. On the contrary, according to Bayesian Optimization A using the objective function including self-extinguishing time and retention and according to Bayesian Optimization B using the objective function including self-extinguishing time, retention, and latter retention, the termination conditions were not satisfied by performing Bayesian Optimization once. Therefore, it was confirmed that optimization efficiency was improved by reducing time taken for Bayesian Optimization by considering the final discharge capacity and the latter retention as the objective function.

In the objective function, Elc(SET) is a maximum value of the acquisition function satisfying a self-extinguishing time less than 6 sec/g, Elc(Ret) is a maximum value of the acquisition function satisfying a retention greater than 80%, Elc(FDC) is a maximum value of the acquisition function satisfying a final discharge capacity greater than 148 mAh/g, and Elc(Lat) is a maximum value of the acquisition function satisfying a latter retention greater than 95%. The number in front of the acquisition function is a weight.

Although embodiments are described above with reference to illustrated drawing, the present inventive concept is not limited thereto. It is obvious that various alternations and modifications will be apparent to one or ordinary skill in the art to which this application belongs within protection coverage of the inventive concept.

According to an embodiment, an electrolyte for lithium secondary batteries having safety and excellent charging and discharging characteristics may be provided effectively by combining machine learning and Bayesian Optimization.

An optimal composition of an electrolyte may be provided more effectively via Bayesian Optimization in which long-term lifespan characteristics of the lithium secondary battery such as retention, final discharge capacity, and latter retention are considered in combination with a stability index.

That is, an electrolyte for lithium secondary batteries having safety and excellent charging and discharging characteristics may be provided effectively by introducing new parameters such as latter retention and final discharge capacity in the case where machine learning is combined with Bayesian Optimization.

In addition, an optimal composition of an electrolyte may be provided in a reduced time compared to Bayesian Optimization in which retention is considered by performing Bayesian Optimization in which latter retention is considered.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by those of ordinary skill in the art that various changes in form and details may be made therein without departing from the spirit and scope of the disclosure as defined by the following claims.

What is claimed is:

1. A method of optimizing an electrolyte for a lithium secondary battery, the method comprising:
preparing a first data set comprising a first formulation and data obtained from the first formulation;
obtaining a second formulation from the first data set by Bayesian Optimization;
obtaining data from the second formulation;
preparing an updated first data set comprising an updated first formulation and data obtained from the updated first formulation by updating the first formulation and the data obtained from the first formulation by using the second formulation and the data obtained from the second formulation, respectively; and
determining whether termination conditions are satisfied,
wherein the obtaining of the second formulation, the obtaining of the data from the second formulation, and the preparing of the updated first data set are repeated until the termination conditions are satisfied,
the data obtained from the first formulation comprises first data obtained from an electrolyte prepared by the first formulation and second data obtained from a lithium secondary battery prepared by using the electrolyte, and
the second data comprise a latter retention and a final discharge capacity.

2. The method of claim 1, wherein the data obtained from the first formulation comprises primary data obtained from the first formulation, secondary data obtained by additional calculation from the primary data, or a combination thereof.

3. The method of claim 1, wherein the second formulation comprises a composition corresponding to a maximum value of an acquisition function or an approximate value thereof in the obtaining of the second formulation by Bayesian Optimization,
the maximum value of the acquisition function comprises a maximum value of an acquisition function corresponding to the first data or an approximate value thereof and a maximum value of an acquisition function corresponding to the second data or an approximate value thereof, and
a weight applied to the maximum value of the acquisition function corresponding to the first data or the approximate value thereof is smaller than a weight applied to the maximum value of the acquisition function corresponding to the second data or the approximate value thereof.

4. The method of claim 1, wherein the latter retention is a ratio Cf/Ca of a final discharge capacity Cf at the last cycle to a latter discharge capacity Ca at a cycle over 20% of the total number of cycles from the first cycle.

5. The method of claim 1, wherein the final discharge capacity is a discharge capacity at the last cycle while measuring retentions.

6. The method of claim 1, wherein the second data further comprises a retention.

7. The method of claim 1, wherein the first data comprises a self-extinguishing time.

8. The method of claim 1, wherein the first data further comprises an ionic conductivity.

9. The method of claim 1, wherein the first data further comprises a cumulative discharge capacity.

10. The method of claim 1, wherein the first formulation comprises a primary formulation prepared empirically or by sampling, a secondary formulation prepared by additional calculation from the primary formulation, or a combination thereof, wherein the first formulation comprises a composition or a composition set including a plurality of compositions.

11. The method of claim 10, wherein the sampling comprises grid sampling, random sampling, latin hypercube sampling, or orthogonal sampling.

12. A system for optimizing an electrolyte for a lithium secondary battery, comprising:
an evaluator configured to obtain data from a first formulation or a second formulation;
a formulation generator configured to obtain a second formulation by applying a first data set including the first formulation and data obtained from the first formulation to Bayesian Optimization;
an updater configured to prepare an updated first data set comprising an updated first formulation and data obtained from the updated first formulation by updating the first formulation and the data obtained from the first formulation by respectively using the second formulation and data obtained from the second formulation; and
a termination determiner configured to determine whether termination conditions are satisfied,
wherein the obtaining of the second formulation, the obtaining of the data from the second formulation, and the preparing of the updated first data set are repeated until the termination conditions are satisfied,
the data obtained from the first formulation comprises first data obtained from an electrolyte prepared by the first formulation and second data obtained from a lithium secondary battery prepared by using the electrolyte, and
the second data comprises a latter retention and a final discharge capacity.

13. The system of claim 12, wherein the data obtained by the evaluator comprises primary data obtained from the first formulation or the second formulation, secondary data obtained from the primary data by additional calculation, or a combination thereof.

14. The system of claim 12, wherein the latter retention is a ratio Cf/Ca of a final discharge capacity Cf at the last cycle to a latter discharge capacity Ca at a cycle over 20% of the total number of cycles from the first cycle.

15. The system of claim 12, wherein the final discharge capacity is a discharge capacity at the last cycle during measuring of retentions.

16. The system of claim 12, wherein the first data comprises a self-extinguishing time.

17. The system of claim 12, wherein the first data further comprises a cumulative discharge capacity.

18. An electrolyte for a lithium secondary battery prepared from a formulation obtained by the method of optimizing an electrolyte for a lithium secondary battery according to claim 1.

19. The electrolyte of claim 18, wherein the electrolyte comprises a cyclic carbonate solvent, a fluorine-containing ester solvent, an additive, and a lithium salt.

20. A lithium secondary battery comprising the electrolyte for a lithium secondary battery of claim 18.
